(19) United States
(12) Patent Application Publication
(10) Pub. No.: US 2005/0123858 A1
(43) Pub. Date: Jun. 9, 2005

(54) Method for forming pattern and method for manufacturing semiconductor device

(76) Inventors: Takeshi Ito, Yokohama-shi (JP); Koji Hashimoto, Yokohama-shi (JP); Tadahito Fujisawa, Tokyo (JP)

Correspondence Address: Finnegan, Henderson, Farabow,;Garrett & Dunner, L.L.P., 1300 I Street, N.W., Washington, DC, 20005-3315, US

(21) Appl. No.: 10/969,174

(22) Filed: Oct. 21, 2004

(30) Foreign Application Priority Data
Oct. 24, 2003 (JP) P2003-364387

(51) Int. Cl. G03F 7/00

(52) U.S. Cl. 430/312; 430/330

(57) ABSTRACT

A method for forming a pattern having holes arrayed with spacing less than resolution of exposure tool, includes forming first resist pattern including first resist openings having width and spacing equal to or greater than the resolution, in first resist film coated on underlying film. First shrank pattern including first holes having dimension equal to or less than the resolution in the underlying film is formed by first shrink process to the first resist pattern. Second resist pattern including second resist openings arrayed between the first holes having width equal to or greater than the resolution, is formed in second resist film coated on the underlying film. Second shrank pattern including second holes having dimension equal to or less than the resolution in the underlying film is formed by second shrink process to the second resist pattern.

### CROSS REFERENCE TO RELATED APPLICATIONS

This application is based upon and claims the benefit of priority from prior Japanese Patent Application P2003-364387 filed on Oct. 24, 2003; the entire contents of which are incorporated by reference herein.

### BACKGROUND OF THE INVENTION

1. Field of the Invention

The present invention relates to a method for forming a pattern in a semiconductor device manufacturing process, and more particularly to a method for forming a fine hole pattern having a dimension equal to or less than a value of a resolution of an exposure tool and to a method for manufacturing a semiconductor device.

2. Description of the Related Art

As of now, miniaturization in semiconductor processes is advancing year after year. Photolithography is one of fine processing technologies for patterning layered films used for manufacturing a semiconductor device.

In fine processing, an underlying film such as an insulating film and a conductive film is processed by etching using a resist pattern formed by photolithography as a mask. In photolithography, a semiconductor device pattern is transferred by use of an exposure tool onto a semiconductor substrate on which a resist film as a photosensitive material is coated. To be concrete, an exposure light emitted from a light source transmits through a photomask on which a transferred pattern of the semiconductor device is delineated, and the pattern is reduced in an optical system. Thereafter, the pattern is projected onto the semiconductor substrate so as to form a resist pattern.

For example, when a contact hole is formed in an insulating film deposited on a semiconductor substrate, a resist film is coated on a surface of the insulating film to be processed, and the resist film is exposed by use of a photomask having a plurality of transparent portions. Next, the resist film is developed so as to form a resist opening pattern having openings in the exposed portions. Thereafter, the insulating film is etched by use of the resist opening pattern as a mask. Thus, contact holes are formed. It should be noted that the photolithography technique is used not only for forming contact holes, but also for doping impurities in the semiconductor substrate, fabricating wiring patterns, and the like, in various manufacturing processes of semiconductor devices.

However, in photolithography, there is a limitation that a dimension of a fine hole pattern depends on an optical resolution of an exposure tool. Here, an “optical resolution of an exposure tool” (hereinafter referred to “resolution”) is defined as a minimum printable feature size achieved by the exposure tool. On the other hand, techniques have been developed for achieving a hole pattern having a finer dimension than a critical dimension that can be formed by photolithography, such as a thermal reflow process, a cross-linking layer formation process, and a shrink process by a processing condition.

In a thermal reflow process, an opening pattern having a dimension almost equal to a value of a resolution by photolithography is formed on a resist film. Thereafter, the resist opening pattern is subjected to a thermal treatment so as to soften the resist film. Thus, a space width of the resist opening pattern is reduced to the value of the resolution or less (see Japanese Patent Laid-Open No. 2001-194769).

In a cross-linking layer formation process, a resist opening pattern having a dimension almost equal to a value of a resolution by photolithography is formed on a resist film containing a photo-induced acid generator. Next, the resist opening pattern is covered with a framed resist film which is cross-linked by a supply of acid. The acid is allowed to move from the resist opening pattern to the framed resist film by heating the resist film, and a cross-linking layer created in an interface is formed as a coverage layer of the resist opening pattern. As a result, the resist opening pattern shrinks so as to reduce a space width of the resist opening pattern to the value of the resolution or less (see Japanese Patent Laid-Open No. 2002-134379).

In the shrink process by a processing condition, a processed material film is etched by use of a resist opening pattern having an opening dimension almost equal to a value of a resolution, which is formed by photolithography, as a mask. When the resist opening pattern is transferred onto an opening pattern of a processed material film, a processing condition is selected, in which a processing conversion difference reducing the opening dimension of the material film to a dimension smaller than the resist opening dimension is generated. As a result, a space width of the opening pattern of the material film is reduced.

However, since it is very difficult for photolithography to form a fine dense pattern having a dimension equal to a value of a resolution or less at intervals narrow than the value thereof, it is difficult to apply any of the foregoing shrink processes to the formation of the dense pattern. Furthermore, when a thermal reflow process is applied to the dense contact hole pattern, reflow is insufficient due to a small amount of resist near the contact holes. Therefore, it is difficult to form a fine contact hole pattern having a hole dimension equal to the value of the resolution or less.

### SUMMARY OF THE INVENTION

A first aspect of the present invention inheres in a method for forming a pattern having a plurality of holes arrayed with a space therebetweew that is less than a resolution of an exposure tool, including coating a first resist film onto an underlying film; forming a first resist pattern having a plurality of first resist openings in the first resist film, each of the first resist openings having a width equal to or greater than the resolution of the exposure tool and arrayed with a spacing between adjacent resist openings equal to or greater than the resolution of the exposure tool; forming a first shrank pattern having a plurality of first holes in the underlying film by a first shrink process applied to the first resist pattern, each of the first holes having a dimension equal to or less than the resolution of the exposure tool; coating a second resist film onto the underlying film after removing the first resist film; forming a second resist pattern having a plurality of second resist openings in the second resist film, each of the second resist openings having a width equal to or greater than the resolution of the exposure tool, arrayed between the first holes; and forming a second shrank pattern having a plurality of second holes in the underlying film by a second shrink process applied to the second resist pattern, each of the second holes having a dimension equal to or less than the resolution of the exposure tool.

A second aspect of the present invention inheres in a method for manufacturing a semiconductor device having a plurality of holes arrayed with a space therebetween that is less than a resolution of an exposure tool, including depositing an underlying film on a surface of a semiconductor substrate; coating a first resist film on the underlying film; forming a first resist pattern having a plurality of resist openings in the first resist film, each of the first resist openings having a width equal to or greater than the resolution of the exposure tool and arrayed with a spacing between adjacent resist openings equal to or greater than the resolution of the exposure tool; forming a first shrank pattern having a plurality of first holes in the underlying film by a first shrink process applied to the first resist pattern, each of the first holes having a dimension equal to or less than the resolution of the exposure tool; coating a second resist film onto the underlying film after removing the first resist film; forming a second resist pattern having a plurality of second resist openings in the second resist film, each of the second resist openings having a width equal to or greater than the resolution of the exposure tool, arrayed between the first holes; and forming a second shrank pattern having a plurality of second holes in the underlying film by a second shrink process applied to the second resist pattern, each of the second holes having a dimension equal to or less than the resolution of the exposure tool.

### BRIEF DESCRIPTION OF DRAWINGS

FIG. 1 is a schematic diagram of an exposure tool used for explaining a method for forming a pattern according to embodiments of the present invention.

FIG. 2 is a schematic view showing an example of a layout pattern used for explaining a method for forming a pattern according to the embodiments of the present invention.

FIGS. 3A and 3B are diagrams showing an example of a first photomask according to a first embodiment of the present invention.

FIGS. 4A and 4B are diagrams showing an example of a second photomask according to the first embodiment of the present invention.

FIG. 5 is a diagram showing an example of an overlay of the first and second photomasks according to the first embodiment of the present invention.

FIGS. 6A and 6B are diagrams explaining an example of a pattern for applying a shrink process according to a first example of the first embodiment of the present invention.

FIGS. 7A and 7B are diagrams showing an example of a pattern formed by a shrink process according to the first example of the first embodiment of the present invention.

FIGS. 8A and 8B are diagrams showing an example of a relation between a depth of focus and an exposure latitude of the shrink process according to the first example of the first embodiment of the present invention, and an example of a relation between a space shrinkage and a resist pattern space.

FIGS. 9 to 18 are cross-sectional views for explaining the pattern formation process according to the first example of the first embodiment of the present invention.

FIG. 19 is a plan view showing an example of a hole pattern formed by the shrank pattern formation process according to the first example of the first embodiment of the present invention.

FIGS. 20A and 20B are a plan view and a cross-sectional view showing an example of a pattern for applying a shrink process according to a second example of the first embodiment of the present invention.

FIGS. 21 to 23 are cross-sectional views for explaining the shrink process according to the second example of the first embodiment of the present invention.

FIGS. 24 to 31 are cross-sectional views for explaining a shrank pattern formation process according to the second example of the first embodiment of the present invention.

FIGS. 32A and 32B are diagrams for explaining an example of a pattern for applying a shrink process according to a third example of the first embodiment of the present invention.

FIG. 33 is a diagram for explaining an example of the pattern formed by the shrink process according to the third example of the first embodiment of the present invention.

FIG. 34 is a diagram for explaining other example of the pattern formed by a shrink process according to the third example of the first embodiment of the present invention.

FIGS. 35 to 39 are cross-sectional views for explaining the shrank pattern formation process according to the third example of the first embodiment of the present invention.

FIGS. 40A and 40B are diagrams for showing one example of a first photomask according to a second embodiment of the present invention.

FIG. 41 is a diagram for showing one example of a second photomask according to a second embodiment of the present invention.

FIGS. 42 to 47 are cross-sectional views for explaining a shrank pattern formation process according the second embodiment of the present invention.

FIGS. 48A and 48B are diagrams showing other example of a first photomask according to the second embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

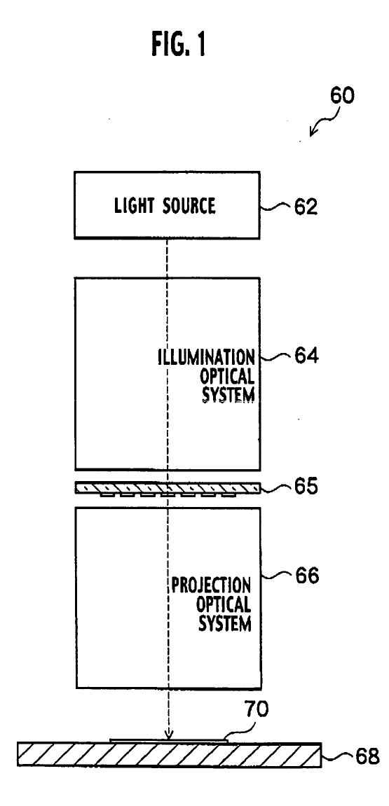

Prior to descriptions of embodiments of the present invention, an exposure tool 60 used for explaining a method for forming a pattern will be described. The exposure tool 60 is a reduction projection exposure tool (stepper), as shown in FIG. 1, with a reduction ratio of 1/4. As a light source 62, an argon fluoride (ArF) excimer laser of a wavelength λ of 193 nm, for example, is used. An illumination optical system 64 includes a fly's eye lens, a condenser lens and the like. A projection optical system 66 includes a projection lens, an aperture stop and the like, By an exposure light, a pattern of a photomask 65 provided between the illumination optical system 64 and the projection optical system 66 is demagnified and projected onto a semiconductor substrate 70 on a stage 68. A value of a resolution R of a pattern projected onto a surface of the semiconductor substrate 70 by the exposure tool 60 is about 70 nm.

For the sake of convenience of the descriptions, the stepper is shown as the exposure tool 60, however a scanner and the like can be also used. Additionally, though the reduction ratio of the stepper is 1/4, any reduction ratio can be used, Furthermore, although the ArF excimer laser is used as the light source 62, other excimer laser such as krypton fluoride (KrF), and an ultraviolet ray such as i-ray and g-ray may be used. In the following descriptions, a dimension of the pattern on the photomask 65 is described in terms of a dimension demagnified and projected on the semiconductor substrate 70, unless otherwise noticed.

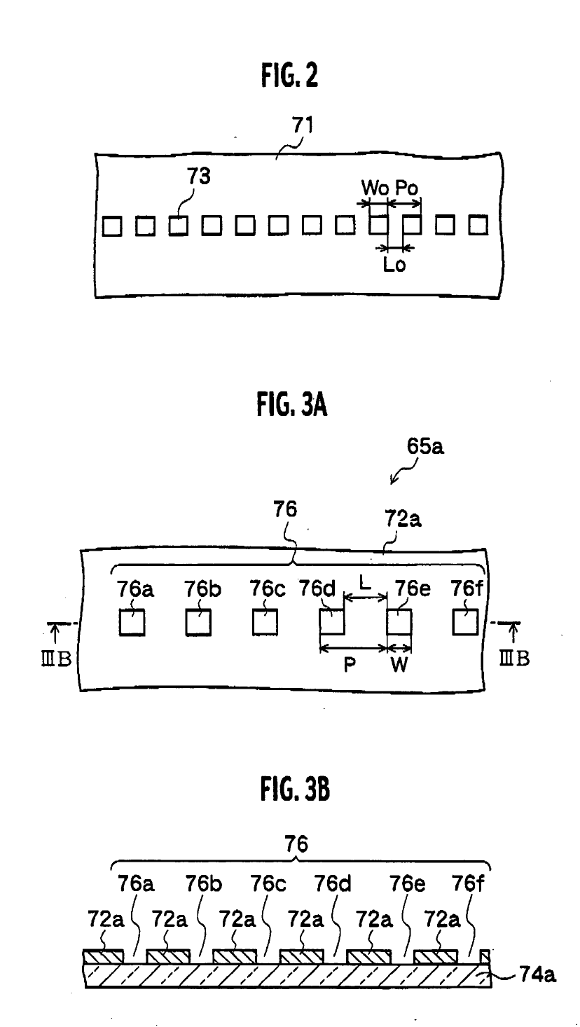

FIG. 2 is an example of a layout pattern 71 of a dense pattern in which a plurality of openings 73, such as a contact hole provided in an underlying layer on a semiconductor substrate, are arrayed at a dense period Po aligned inline. Herein, a “dense pattern” means a pattern in which the opening 73 having the width Wo which is a dimension equal to or less than a value of the resolution R of the exposure tool 60 are arrayed densely at a spacing Lo having a dimension equal to or less than the value of the resolution R. Furthermore, a “dense period” means a period of the dense pattern array. As an example, in the description, the width Wo and the spacing Lo are provided as 70 nm, and the dense period Po is provided as 140 nm. However, the width Wo, the spacing Lo and the dense period Po are not particularly limited, as long as the width Wo, the spacing Lo and the dense period Po have dimension equal to or less than the value of the resolution R of an exposure tool.

### First Embodiment

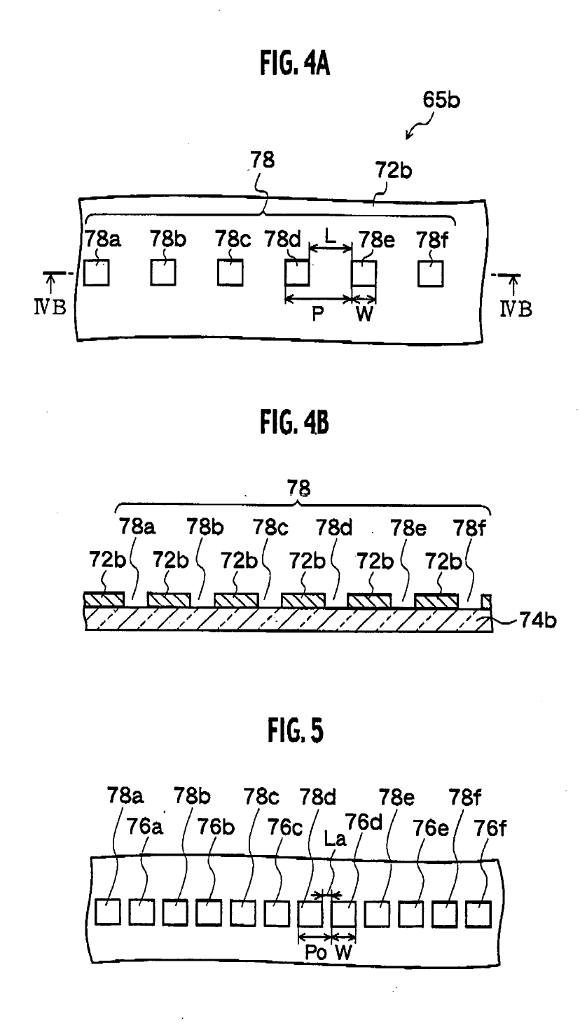

In a method for forming a pattern according to a first embodiment of the present invention, partial exposure by a plurality of photomasks in which the layout pattern 71 having the plurality of openings 73 with the width Wo equal to or less than the value of the resolution of the exposure tool at the dense period Po is divided into a plurality of patterns having a larger period than the dense period Po. Furthermore, in order to provide a pattern transfer margin for photolithography, a width of each openings of the divided pattern of the photomasks is expanded to be equal to or greater than the resolution R. In the first embodiment, as shown in FIGS. 3 and 4, first and second phtomasks 65a and 65b are provided by dividing the layout pattern 71 into two.

As shown in FIGS. 3(a) and 3(b), the first photomask 65a has a first transparent pattern 76 in which a plurality of square-shaped transparent portions 76a to 76f having a width of W are arrayed and aligned inline at a period P, in an opaque film 72a provided on a surface of a transparent substrate 74a. The transparent portions 76a to 76f of the first transparent pattern 76 correspond to every other openings 73 selected in the layout pattern 71 shown in FIG. 2. Accordingly, the period P of the transparent portions 76a to 76f is about 280 nm. If the respective width W of the transparent portions 76a to 76f is set to, for example, about 100 nm which is larger than the value of the resolution R of the exposure tool 60 of FIG. 1, it is possible to ensure a sufficient pattern transfer margin for photolithography. Furthermore, the spacing L between the adjacent transparent portions 76a to 76f is about 180 nm, which is sufficiently larger than the resolution R of the exposure tool 60.

As shown in FIGS. 4A and 43, also the second photomask 65b has a second transparent pattern 78 in which a plurality of square-shaped transparent portions 78a to 78f having a width W are arrayed and aligned inline at a period P in an opaque film 72b provided on a surface of a transparent substrate 74b. The transparent portions 78a to 78f of the second transparent pattern 78 correspond to the remaining openings 73 after selection of the first transparent pattern 76 of layout pattern 71 shown in FIG. 2. Accordingly, the period P of the transparent portions 78a to 78f is about 280 nm. Furthermore, since each width W of the transparent portions 78a to 78f is set to about 100 nm which is larger than the resolution R of the exposure tool 60, each spacing L between the adjacent transparent portions 78a to 78f is about 180 nm, which is sufficiently larger than the resolution R.

As shown in FIG. 5, an overlay of the first and second photomasks 65a and 65b is a pattern in which the respective transparent portions 76a to 76f of the first transparent pattern 76 and the respective transparent portions 78a to 78f of the second transparent pattern 78 are alternately arrayed and aligned inline at the dense period Po as in the case of the layout pattern 71. While the width Wo of the opening 73 of the layout pattern 71 is 70 nm almost equal to the value of the resolution R, the width W of the transparent portions 76a to 76f and 78a to 78f is set to 100 nm larger than the value of the resolution R. As a result, in the overlay shown in FIG. 5, a spacing La between the adjacent transparent portions 76a to 76f and 78a to 78f is as short as 40 nm. It should be noted that a positive type photoresist is used in the partial exposure for forming the hole pattern by the first and second photomasks 65a and 65b.

In the first embodiment, the first transparent pattern 76 of the first photomask 65a is transferred onto a resist film coated onto the underlying film on the semiconductor substrate 70. Since the width W of the transparent portions 76a to 76f of the first transparent pattern 76 and the spacing L between the adjacent transparent portions 76a to 76f are respectively 100 nm and 180 nm, which are sufficiently larger than the value of the resolution R of the exposure tool 60, resist openings transferred from the transparent portions 76a to 76f, are formed with almost equal width W and spacing L of the transparent portions 76a to 76f. A shrink process is applied to the transferred resist openings. Thus, a shrank pattern having a plurality of holes which have a value almost equal to the value of the resolution R are formed in the underlying layer at an almost equal period P of the transparent portions 76a to 76f.

Thereafter, the second transparent pattern 78 of the second photomask 65b is transferred onto a resist film newly coated onto the underlying film in which the shrank pattern is formed from the first transparent pattern 76. The transparent portions 78a to 78f of the second transparent pattern 78 are transferred onto portions of the underlying film between the holes transferred from the respective transparent portions 76a to 76f of the first transparent pattern 76. Another shrink process is applied to the resist openings transferred from the transparent portions 78a to 78f. Thus, another shrank pattern having a plurality of holes which have a dimension almost equal to the value of the resolution R are formed in the underlying film at a period almost equal to the period P of the transparent portion 78a to 78f.

As a result, a pattern having the shrank patterns is formed, in which the plurality of respective holes formed from the first and second transparent patterns 76 and 78 are alternately arrayed. Accordingly, the period of the holes is about 140 nm, which is almost equal to the period Po of the layout pattern 71. In the above described manner, in the first embodiment, the pattern having the width approximately equal to the value of the resolution R at the dense period can be formed by the partial exposure using the first and second photomasks 65a and 65b having the width W and the spacing L, which are larger than the value of the resolution R of the exposure tool 60.

A method for forming a pattern according to the first embodiment, in which the shrink process is applied to the resist pattern formed by the first and second photomasks 65a and 65b, will be described below by first to third examples.

### FIRST EXAMPLE

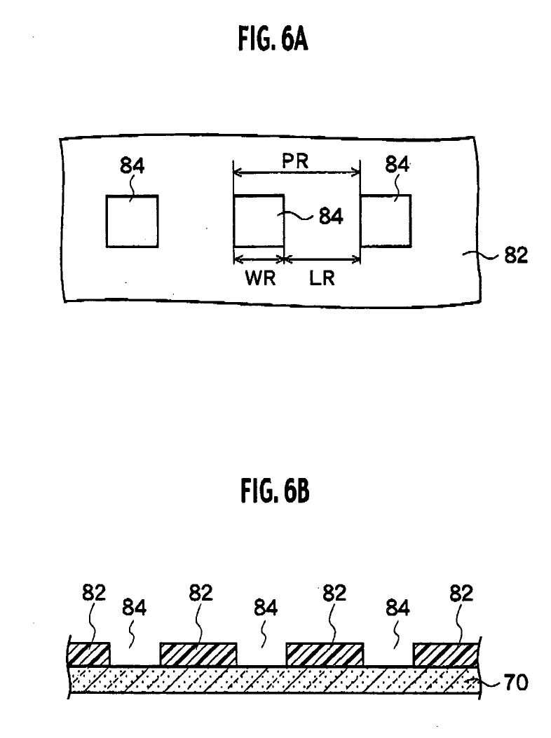

In a first example of the first embodiment of the present invention, a thermal reflow process is used as a shrink process. In the thermal reflow process, the first and second transparent patterns 76 and 78 of the first and second photomasks 65a and 65b are respectively transferred onto a resist film 82 coated on a semiconductor substrate 70, as shown in FIGS. 6A and 6B, and a plurality of resist openings 84 are formed.

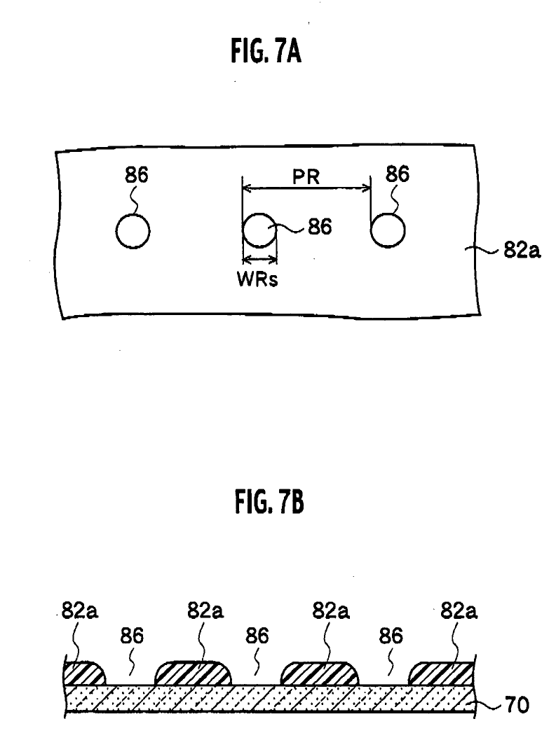

Thereafter, the semiconductor substrate 70 is heated at a temperature range of about 100° C. to about 150° C., for example, to perform a thermal reflow process. Since the resist film 82 around the resist openings 84 shown in FIGS. 6A and 6B, reflows by the thermal reflow process as shown in FIGS. 7A and 7B, the dimension of the width WRs of reduced resist openings 86 formed in a reflow resist film 82a becomes narrow, and the shape of the reduced resist openings 86 becomes round. Since the resist film 82 reflows almost evenly, the value of the period PR of the reduced resist opening 86 is almost equal to the period PR of the resist openings 84.

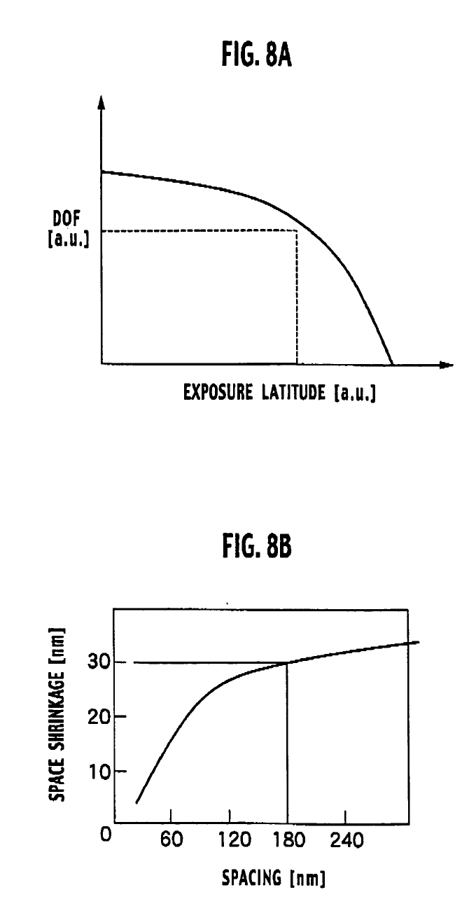

The width W and spacing L of the transparent portions 76a to 76f and 78a to 78f of the first and second transparent patterns 76 and 78 are set to be larger than and the value of the resolution R, and the period P is set to be wider than the dense period Po. In FIG. 8A, the margin curve is illustrated with the solid line showing a relation between an exposure latitude and a depth of focus (DOF), which is provided by lithography simulation assuming a width of the transparent portions to be 100 mm and a spacing thereof to be 180 nm. Furthermore, in FIG. 8A, the minimum exposure latitude and DOF required in manufacturing the semiconductor device are illustrated by the dotted line. For example, when the margin curve intersects the dotted line, the exposure latitude and the DOF is insufficient for variations of an exposure dose and focus. As a result, the transparent portions cannot be transferred faithfully. In the first example, the dimensions of the width W and spacing L of the transparent portions 76a to 76f and 78a to 78f are respectively 100 nm and 180 nm so as to provide a sufficient exposure latitude. Accordingly, the width WR and spacing LR of the transferred resist opening 84 may be 100 nm and 180 nm, respectively.

In FIG. 8B, the relation between an amount of space shrinkage and a resist pattern spacing of the resist opening at a heating temperature of 135° C. for the thermal reflow process is shown. As apparent from FIG. 8B, the amount of space shrinkage increases with an increase of the resist pattern spacing. When the resist pattern spacing is 180 nm, the amount of space shrinkage is 30 nm. Furthermore, since a reflow amount of the resist film around the resist opening becomes insufficient in the range where the resist pattern spacing is equal to or less than the resolution R, the space shrink amount greatly decreases. Therefore, when the heating temperature for the thermal reflow process is 135° C., for example, the width WRs of the reduced resist opening 86 become 70 nm.

As described above, according to the first example, the reduced resist opening 86 having a dimension as fine as the level of the resolution R can be formed. Furthermore, the width WRs of the reduced resist opening 86 can also be formed to a dimension equal to or less than the value of the resolution R depending on the heating temperature of the thermal reflow process and the spacing LR of the resist opening.

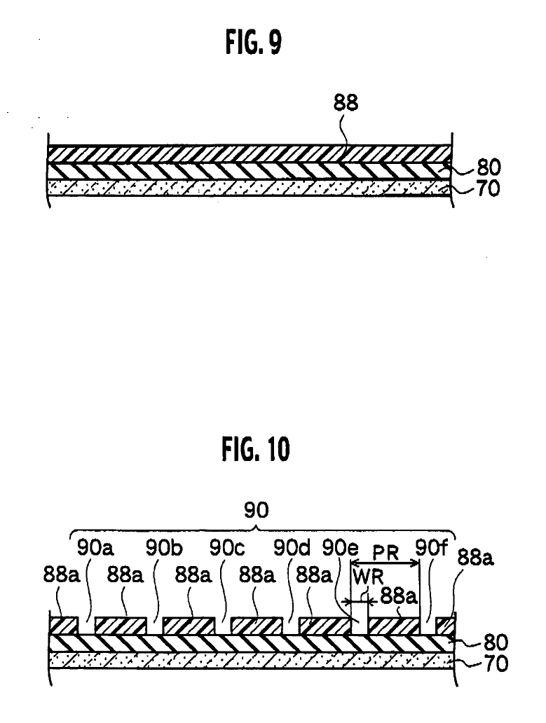

Next, with reference to FIGS. 9 to 18, a method for forming a pattern used for a manufacture of the semiconductor device will be described. As a shrink process, a thermal reflow process is applied to a resist pattern transferred from the first and second photomasks 65a and 65b. It should be noted that the layout pattern 71 as a dense pattern in which the openings 73 are arrayed at the dense period Po shown in FIG. 2 is a contact hole pattern being formed in a underlying film such as an insulating film. A dense pattern is not limited to a contact hole pattern. However, a dense pattern may be other pattern such as a via hole pattern formed in the semiconductor device.

As shown in FIG. 9, a first resist film 88 is coated onto an underlying layer 80 deposited on a surface of the semiconductor substrate 70. The semiconductor substrate 70 and the first photomask 65a are placed on the exposure tool 60 of FIG. 1. As shown in FIG. 10, an image of the first transparent pattern 76 is transferred so as to form a first resist pattern 90 having resist openings 90a to 90f in the first resist film 88a. For example, a period PR and width WR of the resist openings 90a to 90f are respectively about 280 nm and about 100 nm.

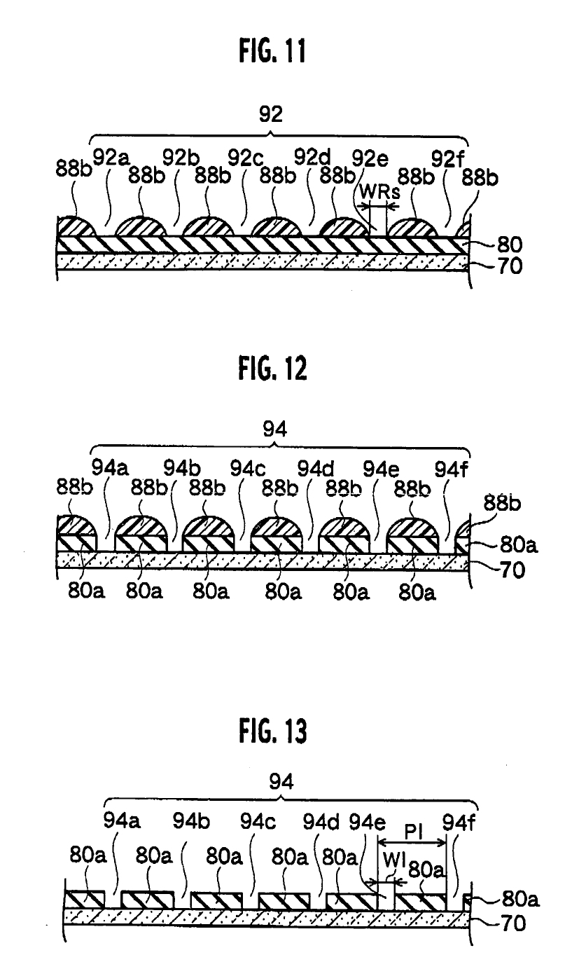

A thermal reflow process is performed by heating the semiconductor substrate 70 at a temperature of 135° C., for example, above which the first resist pattern 90 is formed. As a result, a first reduced resist pattern 92 having reduced resist openings 92a to 92f which are provided by reducing the width WR of the resist openings 90a to 90f, is formed in a first reflow resist film 88b, as shown in FIG. 11. A width WRs of the reduced resist openings 92a to 92f is reduced to about 70 nm almost equal to the resolution R.

The underlying film 80 disposed in the reduced resist openings 92a to 92f is selectively removed by reactive ion etching (RIE) and the like, using the first reflow resist film 88b as a mask. As a result, a first shrank pattern 94 having holes 94a to 94f in the underlying film 80a is formed, as shown in FIG. 12. The first reflow resist film 88b is removed by ashing or the like. Thus, as shown in FIG. 13, the underlying film 80a in which the first shrank pattern 94 having the holes 94a to 94f with a width WI of about 70 nm at a period PI of about 280 nm is formed, is provided on the surface of the semiconductor substrate 70.

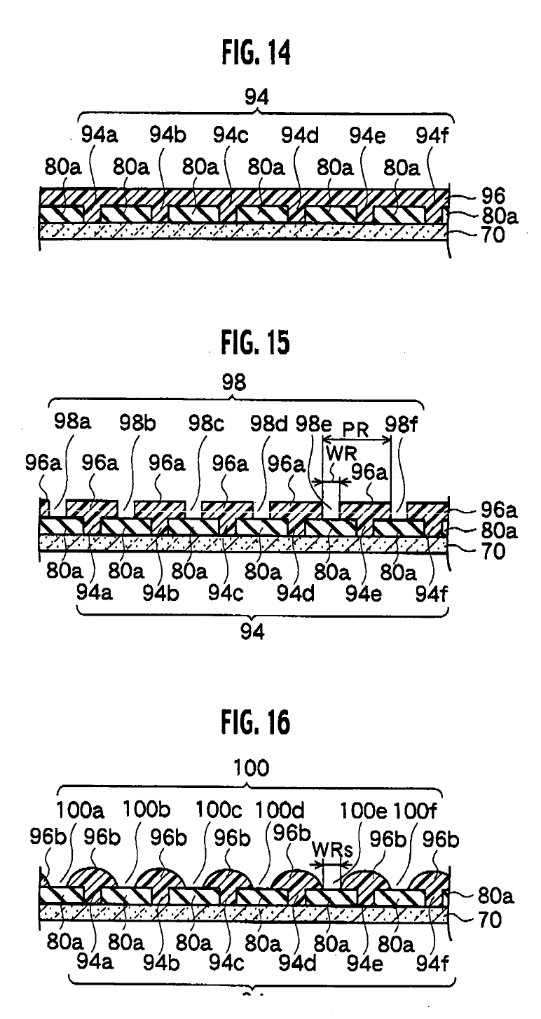

As shown in FIG. 14, a second resist film 96 is coated onto the underlying film 80a in which the first shrank pattern 94 is provided on the surface of the semiconductor substrate 70. The semiconductor substrate 70 and the second photomask are placed on the exposure tool 60. Here, the transparent portions 78a to 78f of the second transparent pattern 78 are overlaid so that each of the transparent portions 78a to 78f is projected onto a central portion of the underlying film 80a between the respective holes 94a to 94f of the first shrank pattern 94. An image of the second transparent pattern 78 is transferred so as to form a second resist pattern 98 having resist openings 98a to 98f in the second resist film 96a, as shown in FIG. 15. A period PR and width WR of the resist openings 98a to 98f are about 280 nm and about 100 nm respectively.

The semiconductor substrate 70, above which the second resist pattern 98 is formed, is heated for implementing a thermal reflow process, As a result, as shown in FIG. 16, a second reduced resist pattern 100 having reduce resist openings 100a to 100f which are provided by reducing the width WR of the resist openings 98a to 98f, is formed in the second reflow resist film 96b. The width WRs of the reduced resist openings 100a to 100f is reduced to about 70 nm almost equal to the resolution R.

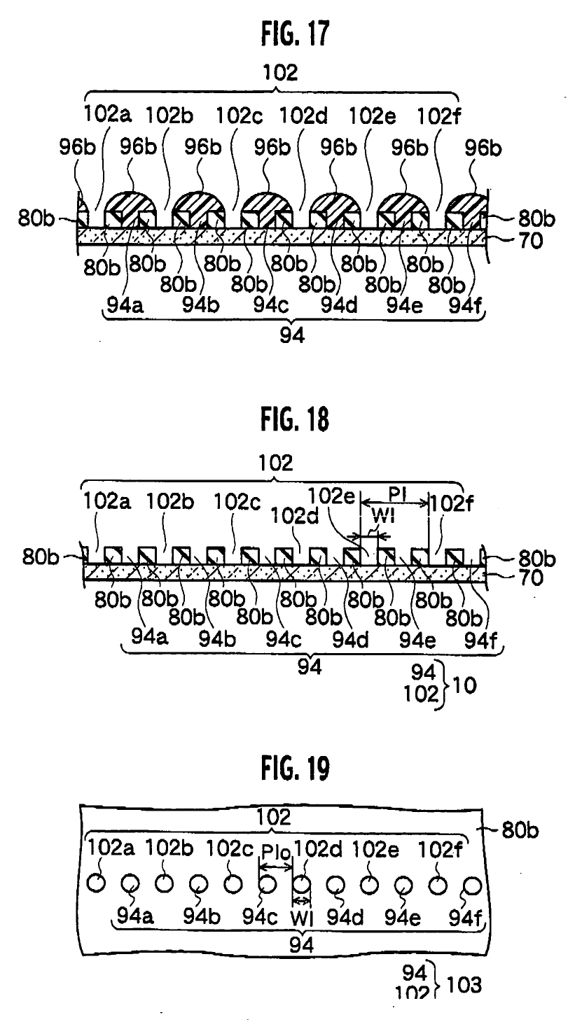

The underlying film 80a disposed in the reduced resist openings 100a to 100f is selectively removed by RIE and the like, using the second reflow resist film 96b as a mask. As a result, as shown in FIG. 17, a second shrank pattern 102 having holes 102a to 102f in the underlying film 80b is formed. The second reflow resist film 96b is removed by ashing or the like. As shown in FIG. 18, each of the holes 102a to 102f of the second shrank pattern 102 having a width WI of about 70 nm and a period PI of about 280 nm is provided between the respective holes 94a to 94f of the first shrank pattern 94 on the surface of the semiconductor substrate 70. Thus, a hole pattern 103 is provided in the underlying film 80b.

In the hole pattern 103 comprising the first and second shrank patterns 94 and 102, the holes 94a to 94f and 102a to 102f, which have a period PIo of about 140 nm and a width WI of about 70 nm, are alternatively arrayed as shown in FIG. 19. In the method for forming a pattern according to the first example of the first embodiment, it is possible to form the hole pattern 103 having the dense period PIo and the width WI almost equal to the value of the resolution R by partial exposure using the fist and second photomasks 65a and 65b.

In the first example of the first embodiment, the layout pattern 71 is divided into two sections. However, when the dense period Po of the layout pattern 71 is further decreased so as to reduce a dimension of the hole pattern less than the resolution R, the layout pattern 71 may be divided into three or more sections in view of reflow characteristics of a resist film.

### SECOND EXAMPLE

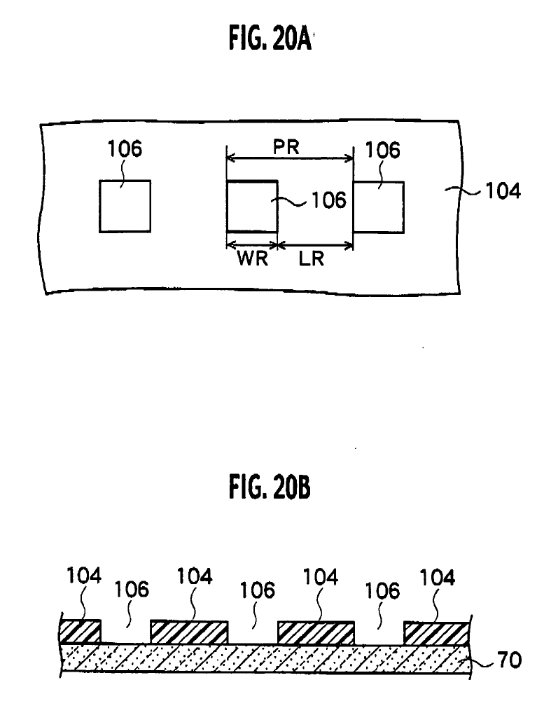

In a second example of the first embodiment of the present invention, a cross-linking layer formation process is used as a shrink process. As shown in FIGS. 20A and 20B, in the cross-linking layer formation process, the first transparent pattern 76 of the first photomask 65a shown in FIG. 3A or the second transparent pattern 78 of the second photomask 65b shown in FIG. 4A is projected onto a resist film 104 containing a photo-induced acid generator, which is coated onto the semiconductor substrate 70. Thus, a plurality of resist openings 106 are delineated. The resist openings 106 are transferred so as to have a width WR, a spacing LR and a period PR which are almost equal to the width W, the spacing L and the period P of the transparent portions 76a to 76f and 78a to 78f of the first and second transparent patterns 76 and 78. As the photo-induced acid generator contained in the resist film 104, sulfonium salt, urea and the like, are used.

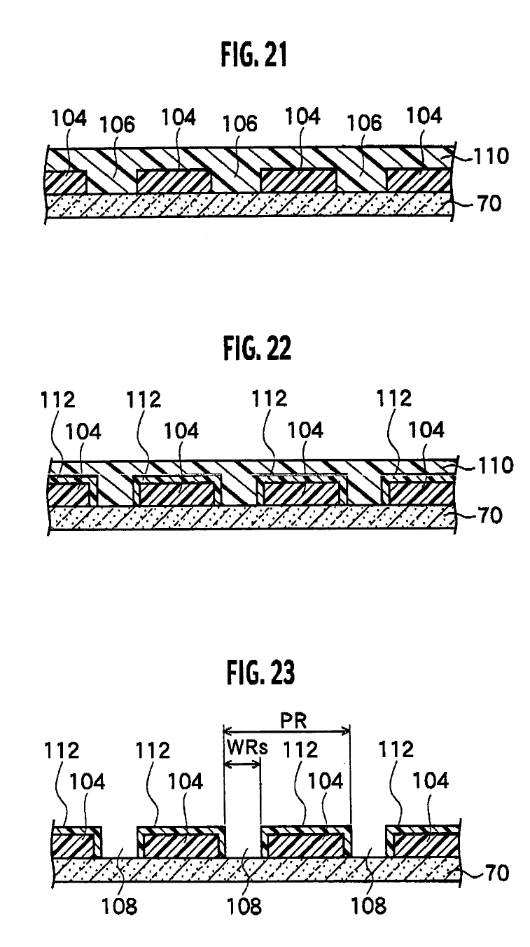

Thereafter, as shown in FIG. 21, a framed resist film 110 containing a cross-linking agent is coated onto the semiconductor substrate 70 having the resist film 104. As the cross-linking agent, a water-soluble cross-linking agent such as a urea compound, a melamine compound and the like, which is heat-curable, is used. By baking at about 100° C. to about 120° C., for example, after coating the framed resist film 110, acid in the resist film 104 generated during exposure, diffuses into the framed resist film 110, and a cross-linking layer 112 thermally cured by the acid is grown so as to cover a sidewall and a surface of the resist film 104, as shown in FIG. 22. Thereafter, the uncross-linking framed resist film 110 is removed. Thus, reduced resist openings 108 are formed surrounded with the cross-linking layer 112 grown on the resist film 104, as shown in FIG. 23. The width WRs of the reduced resist openings 108 is smaller compared to the width WR of the resist openings 106 due to a thickness of the cross-linking layer 112. On the other hand, since the cross-linking layer 112 is grown with isotropic manner, the period PR of the reduced resist openings 108 does not change. The width WRs of the reduced resist openings 108 depends on a baking temperature. For example, when the baking is performed at 110° C., the width WRs of the reduced resist openings 108 is about 70 nm. The width WRs of the reduced resist openings 108 may be reduced to a value almost equal to the resolution R. In addition, if conditions of the baking are suitably applied, the width WRs of the reduced resist openings 108 can be reduced below the resolution R.

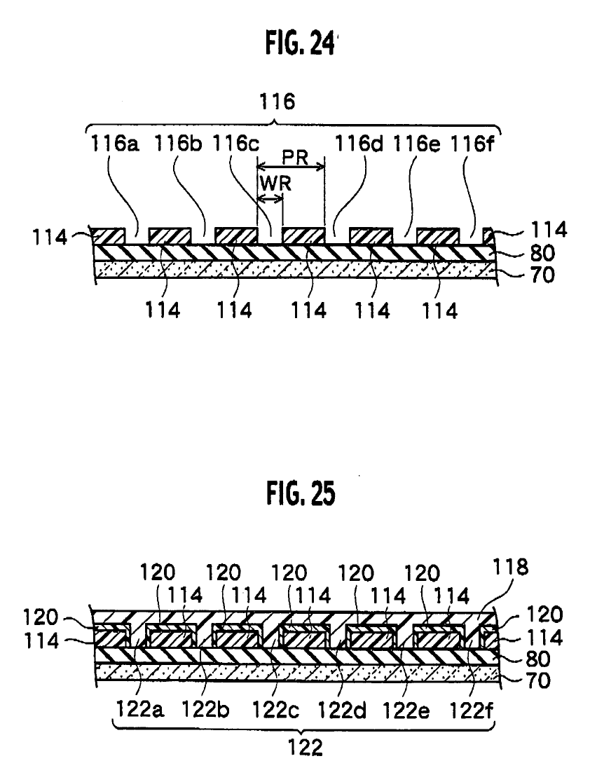

Next, a method for forming a pattern used in manufacturing the semiconductor device with reference to FIGS. 24 to 31 by applying a cross-linking layer formation process as a shrink process to the resist pattern transferred from the first and second photomasks 65a and 65b.

A resist film containing photo-induced acid generator is coated onto an underlying film 80 deposited on a surface of the semiconductor substrate 70. The semiconductor substrate 70 and the first photomask 65a are placed on the exposure tool 60 shown in FIG. 1. An image of the first transparent pattern 76 is transferred so as to form a first resist pattern 116 having resist openings 116a to 116f in the first resist film 114, as shown in FIG. 24. For example, a period PR and width WR of the resist openings 116a to 116f are respectively about 280 nm and about 100 nm.

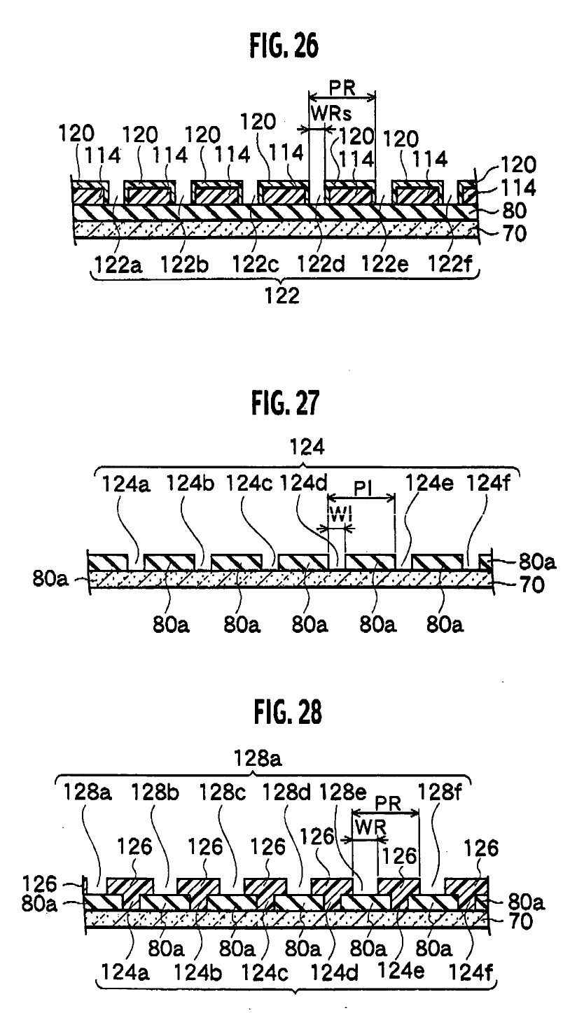

A first framed resist film 118 containing a cross-linking agent is coated onto the first resist pattern 116 above the semiconductor substrate 70, as shown in FIG. 25. Baking is performed by heating the first framed resist film 118 at about 110° C. As a result, a first cross-linking layer 120 is grown so as to cover a sidewall and a surface of the first resist film 114. Thus, a first reduced resist pattern 122 having reduced resist openings 122a to 122f is formed. Thereafter, by removing the first framed resist film 118 which remains without cross-linking, the reduced resist openings 122a to 122f of the first reduced resist pattern 122 which exposes the underlying film 80 is provided, as shown in FIG. 26. The width Wrs of the reduced resist openings 122a to 122f having the same period PR of the first resist film 114 is reduced to about 70 nm almost equal to the resolution R.

Using the first resist film 114 covered with the first cross-linking layer 120 as a mask, the underlying film 80 disposed in the reduced resist openings 122a to 122f is selectively removed by RIE or the like. The first resist film 114 covered with the first cross-linking layer 120 is removed by ashing or the like. Thus, as shown in FIG. 27, the underlying film 80a in which a first shrank pattern 124 having holes 124a to 124f with a period PI of about 280 nm and a width WI of about 70 nm is formed, is provided above the surface of the semiconductor substrate 70.

A resist film containing photo-induced acid generator is coated onto the underlying film 80a in which the first shrank pattern 124 is provided on the surface of the semiconductor substrate 70. The semiconductor substrate 70 and the second photomask 65b are placed on the exposure tool 60. Here, the transparent portions 78a to 78f of the second transparent pattern 78 is overlaid so that each of the transparent portions 78a to 78f is projected onto a central portion of the underlying film 80a between the respective holes 124a to 124f of the first shrank pattern 124. An image of the second transparent pattern 78 is transferred, and a second resist pattern 128 having resist openings 128a to 128f is formed in the second resist film 126, as shown in FIG. 28. A period PR and width WR of the resist openings 128a to 128f are about 280 nm and about 100 nm respectively.

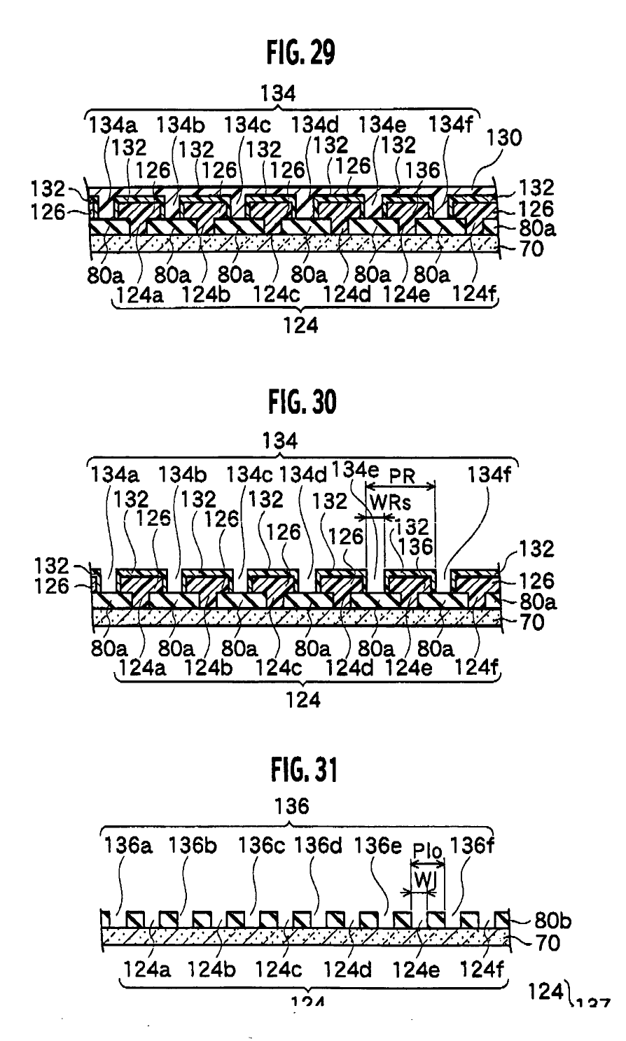

As shown in FIG. 29, a second framed resist film 130 containing cross-linking agent is coated onto the second resist pattern 128 above the semiconductor substrate 70, Baking is performed by heating the second framed resist film 130 at 110° C. As a result, a second cross-linking layer 132 is grown so as to cover a sidewall and a surface of the second resist film 126. Thus, a second reduced resist pattern 134 having reduced resist openings 134a to 134f is formed. Thereafter, by removing the second framed resist film 130 which remains without cross-linking, the reduced resist openings 134a to 134f of the second reduced resist pattern 134 which exposes the underlying film 80a is provided, as shown in FIG. 30. The width WRs of the reduced resist openings 134a to 134f having the same period PR of the second resist film 126 is reduced to about 70 nm almost equal to the resolution R.

The underlying film 80a of the reduced resist openings 134a to 134f is selectively removed by RIE or the like using the second resist film 126 covered with the second cross-linking layer 132 as a mask. The second resist film 126 covered with the second cross-linking layer 132 is removed by ashing or the like. Thus, as shown in FIG. 31, a second shrank pattern 136 having holes 136a to 136f between the respective holes 124a to 124f of the first shrank pattern 124 is formed in the underlying layer 80b on the surface of the semiconductor substrate 70. As a result, a hole pattern 137 having a period PIo of about 140 nm and a width WI of about 70 nm is provided in the underlying film 80b.

As described above, in a method for forming a pattern according to the second example of the first embodiment, it is possible to form the hole pattern 137 having the width WI almost equal to the value of the resolution R with the dense period PIo by partial exposure using the first and second photomasks 65a and 65b.

### THIRD EXAMPLE

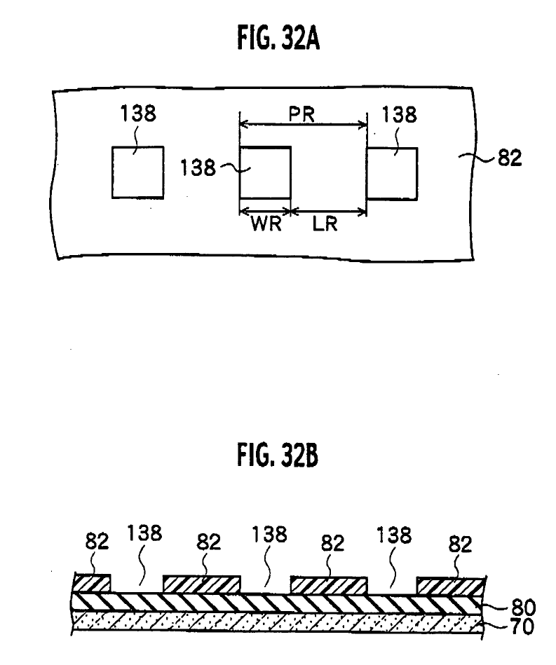

In a third example of the first embodiment of the present invention, as a shrink process, a process providing a processing conversion difference depending on a processing condition is used. Ina shrink process by a processing conversion difference, an image of the first or second transparent patterns 76 and 78 of the first or second photomasks 65a and 65b is transferred onto a resist film 82 coated onto the underlying film 80 on the semiconductor substrate 70 by the exposure tool 60, as shown in FIGS. 32A and 32B. Thus, a plurality of resist openings 138 are delineated. The resist openings 138 are transferred so as to have a width WR, a spacing LR and a period PR, which are almost equal to the width W, the spacing L and the period P of the transparent portions 76a to 76f and 78a to 78f.

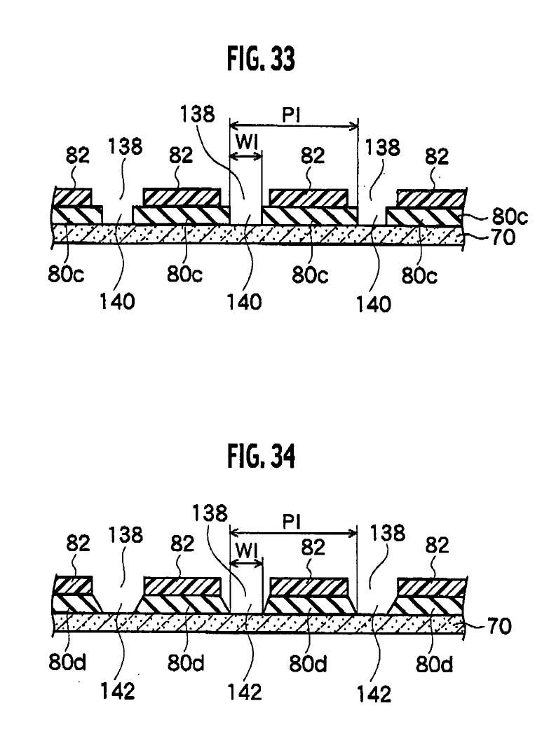

Thereafter, a shrink process is performed by RIE or the like, under an etching condition providing a processing conversion difference, A “processing conversion difference” is defined as a difference in dimension between a mask and a processed pattern, which is generated by processing. For example, as etching conditions, pressure of a mixed gas of perfluorocyclo-butane (C₄F₈) and oxygen (O₂) is about 10 Pa, and temperature at a bottom portion of an etching chamber is about 20° C. lower than temperature of the semiconductor substrate 70 and un upper portion of the etching chamber. Furthermore, a flow rate of the O₂ gas is reduced compared with a flow rate of a C₄F₈ gas, and a high frequency power is applied with about 400 W. Since the etching pressure of the C₄F₈ and O₂ mixed gas is applied with twice higher as an ordinary pressure condition, anisotropic etching is achieved. Furthermore, since the bottom portion of the etching chamber is kept at lower temperature, a reaction product is apt to be deposited at a sidewall of an etched hole. In addition, removal of the deposited reaction product is prevented by reducing the flow rate of the oxygen O₂. As a result, it is possible to achieve a shrink process by processing conditions providing a processing conversion difference, so as not to etch the region near the resist film 82. Thus, as shown in FIG. 33, a width WI of a plurality of holes 140 formed in the underlying film 80c is reduced compared with the width WR of the resist openings 138.

Furthermore, when the semiconductor substrate 70 is etched at a low temperature of, for example, about −10° C. to about −50° C., a mesa-shaped sidewall is provided by a sidewall protection effect due to a polymer film that is a reaction product. In such manner, when a shrink process is performed under the conditions which provide a tilt from an edge of the resist film 82, a width WI of a bottom portion of a plurality of holes 142 formed in the underlying film 80d is reduced compared with the width WR of the resist openings 138, as shown in FIG. 34. In the shrink process shown in FIGS. 33 and 34, the period PI of the holes 140 and 142 is almost equal to the period PR of the resist openings 138.

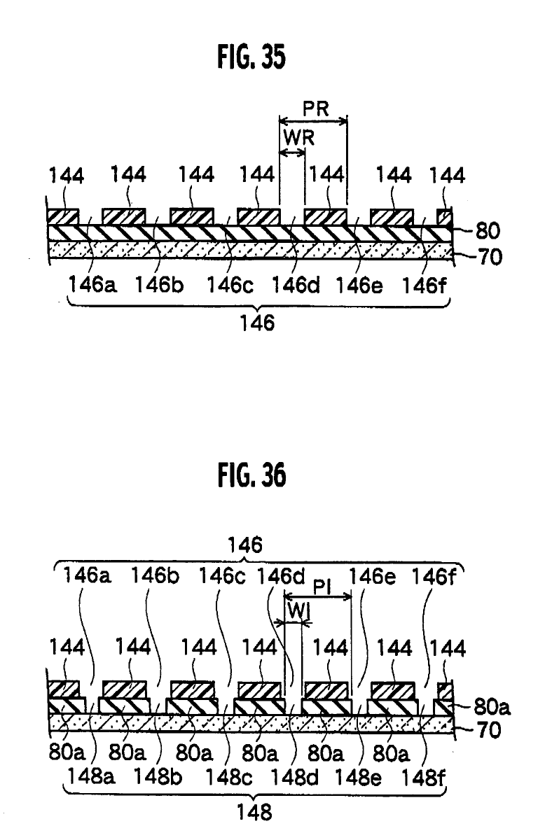

Next, a method for forming a pattern used in manufacturing the semiconductor device by a shrink process using the processing conversion difference shown in FIG. 33 to a resist pattern transferred from the first and second photomasks 65a and 65b will be described with reference to FIGS. 35 to 39.

A resist film is coated onto an underlying film 80 deposited on a surface of the semiconductor substrate 70. The semiconductor substrate 70 and the first photomask 65a are placed on the exposure tool 60 shown in FIG. 1. As shown in FIG. 35, an image of the first transparent pattern 76 is transferred so as to form a first resist pattern 146 having resist openings 146a to 146f in the first resist film 144. For example, a period PR and width WR of the resist openings 146a to 146f are about 280 nm and about 100 nm respectively.

As shown in FIG. 36, a shrink process utilizing the processing conversion difference is performed so as to form a first shrank pattern 148 having holes 148a to 148f in the underlying film Boa on the semiconductor substrate 70. A width WI of the holes 148a to 148f having a period PI almost equal to the period PR of the first resist film 144 is reduced to about 70 nm almost equal to the value of the resolution R.

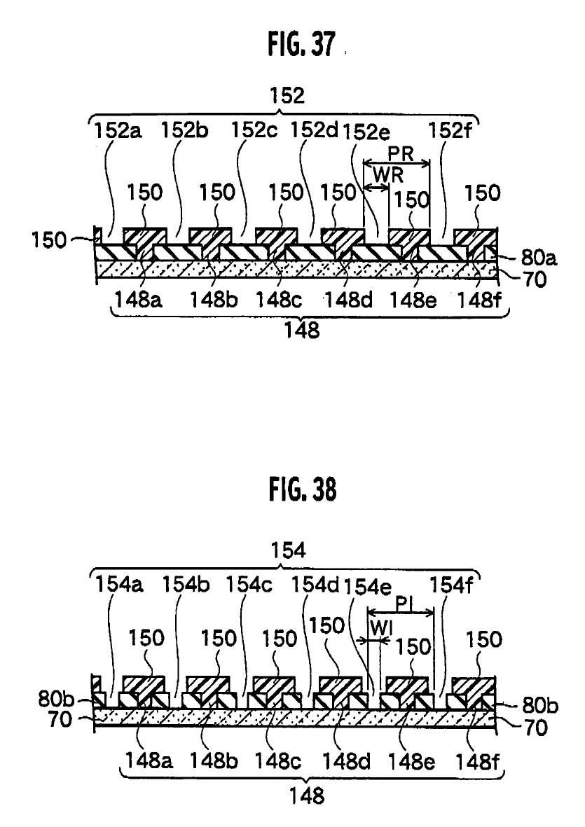

The first resist film 144 is removed by ashing or the like. A resist film is coated onto the underlying film 80a in which the first shrank pattern 148 is provided on the surface of the semiconductor substrate 70. The semiconductor substrate 70 and the second photomask 65b are placed on the exposure tool 60. Here, the transparent portions 78a to 78f of the second transparent pattern 78 are overlaid so that each of the transparent portions 78a to 78f is projected onto a central portion of the underlying film 80a between the holes 148a to 148f of the first shrank pattern 148. An image of the second transparent pattern 78 is transferred, and a second resist pattern 152 having resist openings 152a to 152f is formed in the second resist film 150, as shown in FIG. 37. A period PR and width WR of the resist openings 152a to 152 f are respectively about 280 nm and about 100 mm.

As shown in FIG. 38, a shrink process provided by the processing conversion difference is performed so as to form a second shrank pattern 154 having holes 154a to 154f in the underlying film 80b on the semiconductor substrate 70. A width WI of the holes 154a to 154f having a period PI equal to the period PR of the second resist film 150 is reduced to about 70 nm almost equal to the value of the resolution R.

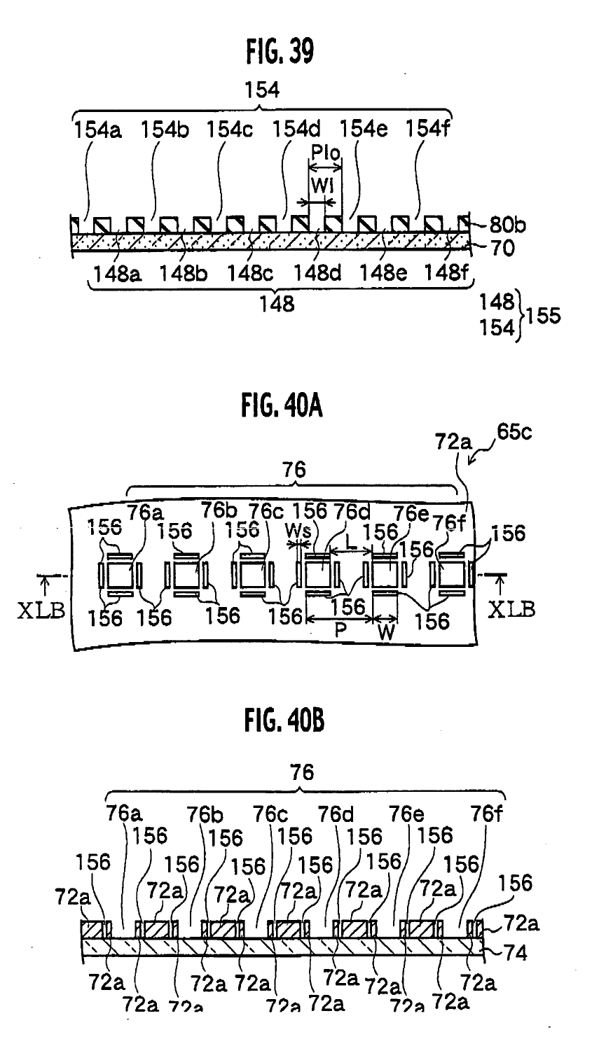

The second resist film 150 is removed by ashing or the like. As shown in FIG. 39, the second shrank pattern 154 having the holes 154a to 154f between the respective holes 148a to 148f of the first shrank pattern 148 on the surface of the semiconductor substrate 70 is formed. As a result, a hole pattern 155 having a period PIo of 140 nm and a width WI of 70 nm is provided in the underlying film 80b.

As described above, in a method for forming a pattern according to the third example of the first embodiment, it is possible to form the hole pattern 155 having the width WI almost equal to the value of the resolution R with the dense period PIo by partial exposure using the first and second photomasks 65a and 65b.

### Second Embodiment

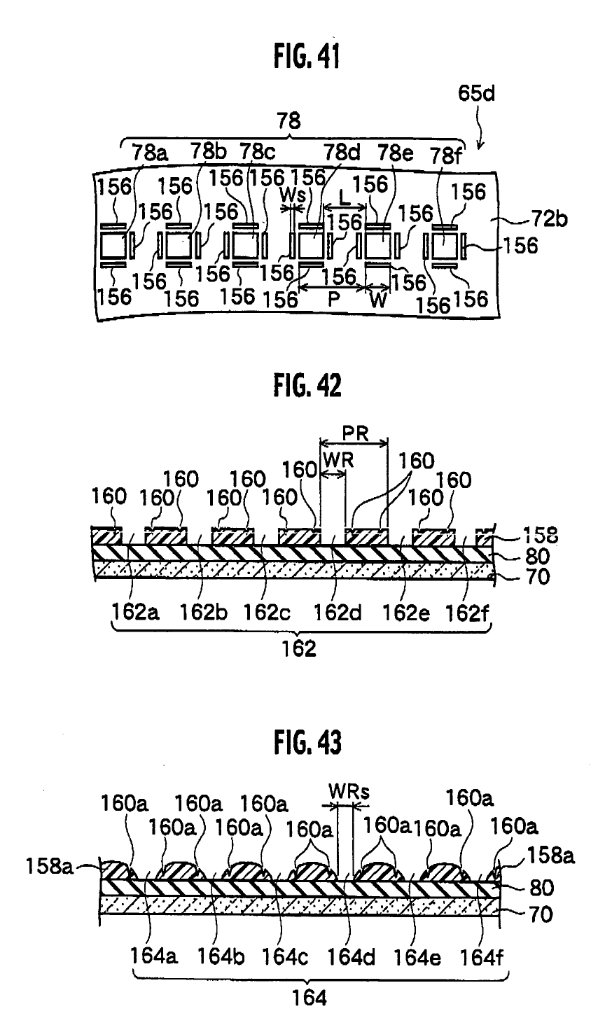

As shown in FIGS. 40A, 40B and 41, first and second photomasks 65c and 65d used in a method for forming a pattern according to a second embodiment of the present invention further include a plurality of sub-resolution assist feature (SRAF) transparent portions (assist pattern) 156 which are respectively disposed around peripheries of the transparent portions 76a to 76f and 78a t0 78f of the first and second photomasks 65a and 65b of the first embodiment shown in FIGS. 3A, 3B, 4A and 4B. The SRAF transparent portions 156 serve to increase a resolution of a projected image when a hole pattern is transferred. In a dense pattern having the dense period Po like the layout pattern 71 shown in FIG. 2, it is difficult to dispose the SRAF transparent portions 156 in the spacing Lo between the openings 73 in terms of a dimension. In the first and second photomasks 65c and 65d, the layout pattern 71 is divided into a plurality of patterns so that a period larger than the dense period Po is provided. Accordingly, a sufficient spacing L for disposing the SRAF transparent portions 156 can be ensured between the respective patterns of the transparent portions 76a to 76f and 78a to 78f.

As shown in FIGS. 40A and 40B, the first photomask 65c has a first transparent pattern 76 in which a plurality of square-shaped transparent portions 76a to 76f having a width W are arrayed with a period P in line in an opaque film 72a provided on a surface of a transparent substrate 74, and the SRAF transparent portions 156 disposed near the four sides of the respective transparent portions 76a to 76f. The SRAF transparent portions 156 have a length in the longitudinal direction in parallel with the four sides of the respective transparent portions 76a to 76f, which is almost equal to the width W of the transparent portions 76a to 76f. A width Ws of the SRAF transparent portions 156 in the lateral direction has a dimension less than the resolution R. The transparent portions 76a to 76f of the first transparent pattern 76 correspond to every other openings 73 in the layout pattern 71 shown in FIG. 2. Therefore, the period P of the transparent portions 76a to 76f is about 280 nm. Furthermore, the width W of the transparent portions 76a to 76f is, for example, about 100 nm equal to or greater than the value of the resolution R of the exposure tool 60 shown in FIG. 1. The spacing L between the adjacent transparent portions 76a to 76f is about 180 nm, which is a value sufficiently large relative to the value of the resolution R of the exposure tool 60.

As shown in FIG. 41, the second photomask 65d also has a second transparent pattern 78 in which a plurality of square-shaped transparent portions 78a to 78f having a width W are arrayed inline at a period P in an opaque film 72b, and SRAF transparent portions 156 disposed near four sides of the transparent portions 78a to 78f. The SRAF transparent portions 156 have a length in the longitudinal direction in parallel with the four sides of the respective transparent portions 78a to 78f, which is almost equal to the width W of the transparent portions 78a to 78f. A width Ws of the SRAF transparent portions 156 in the lateral direction has a dimension less than the value of the resolution. The transparent portions 78a to 78f of the second transparent pattern 78 correspond to the remaining openings 73 after selection of the first transparent pattern 76 of the layout pattern 71 shown in FIG. 2. Therefore, the period P of the transparent portions 78a to 78f is about 280 nm. Furthermore, the width W and spacing L of the transparent portions 78a to 78f are respectively about 100 nm and about 180 nm, which are greater than the value of the resolution R of the exposure tool 60.

The second embodiment differs from the first embodiment in that the SRAF transparent portions 156 are provided in the first and second photomasks 65c and 65d. The second embodiment is the same as the first embodiment in other respects, and duplicated descriptions are omitted.

Next, a method for forming a pattern used in manufacturing the semiconductor device by applying a thermal reflow process as a shrink process to a resist pattern transferred from the first and second photomasks 65c and 65d will be described with reference to FIGS. 42 to 47. A shrink process is not limited to a thermal reflow process. A cross-linking layer formation process, the shrink process by the processing conversion difference, and the like, may be applied.

A resist film is coated onto an underlying film 80 deposited on a surface of a semiconductor substrate 70. The semiconductor substrate 70 and the first photomask 65c are placed on the exposure tool 60 shown in FIG. 1. As shown in FIG. 42, an image of the first transparent pattern 76 is transferred so as to form a first resist pattern 162 having resist openings 162a to 162f in the first resist films 158. For example, a period PR and width WR of the resist openings 162a to 162f are respectively about 280 nm and about 100 nm. It should be noted that pits 160 corresponding to the SRAF transparent portions 156 are generated in ends of the first resist films 158 around the resist openings 162a to 162f.

A thermal reflow process is performed by heating the semiconductor substrate 70 to a temperature above which the first resist opening 90 is formed, for example at a temperature of 135° C. As a result, as shown in FIG. 43, a first reduced resist pattern 164 having reduced resist openings 164a to 164f which are provided by reducing the width WR of the resist openings 162a to 162f, is formed in the first reflow resist film 158a. A width WRs of the reduced resist openings 164a to 164f is reduced to about 70 nm almost equal to the resolution R. The pits 160 remain ir the first reflow resist films 158a around the reduced resist openings 164a to 164f.

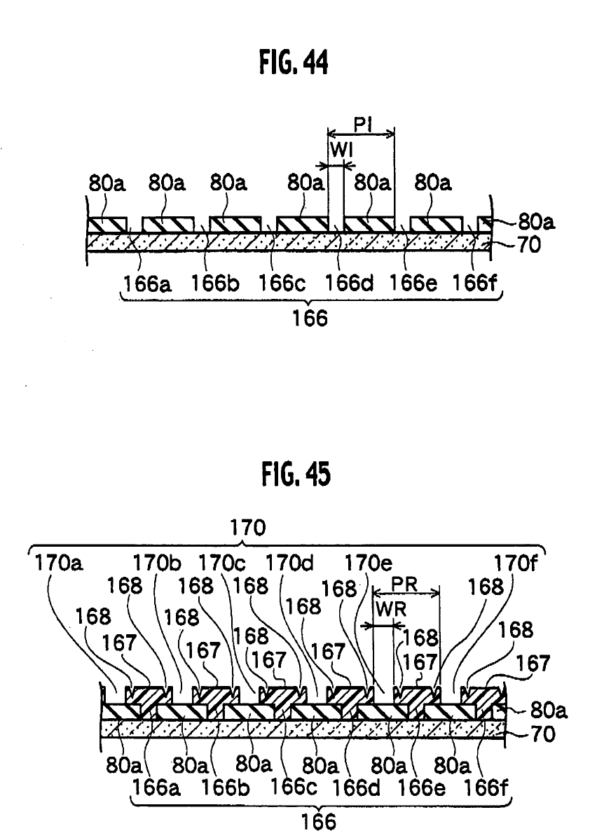

Using the first resist film 158a as a mask, the underlying film 80 disposed in the reduced resist openings 164a to 164f is selectively removed by RIE or the like. Thereafter, the first reflow resist film 158a is removed by ashing or the like. Thus, as shown in FIG. 44, the underlying film 80a in which a first shrank pattern 166 having holes 166a to 166f with a period PI of about 280 nm and a width WI of about 70 nm is formed, is obtained on the surface of the semiconductor substrate 70.

A resist film is coated onto the underlying film 80a in which the first shrank pattern 166 is provided on the surface of the semiconductor substrate 70. The semiconductor substrate 70 and the second photomask are placed on the exposure tool 60. Here, the transparent portions 78a to 78f of the second transparent pattern 78 is overlaid so that each of the transparent portions 78a to 78f is projected onto a central portion of the underlying film 80a between the respective holes 166a to 166f of the first shrank pattern 166. An image of the second transparent pattern 78 is transferred so as to form a second resist pattern 170 having resist openings 170a to 170f in a second resist film 167, as shown in FIG. 45. A period PR and width WR of the resist openings 170a to 170f are about 280 nm and about 100 nm respectively. It should be noted that pits 168 corresponding to the SRAF transparent portions 156 are generated in ends of the second resist film 167 around the resist openings 170a to 170f.

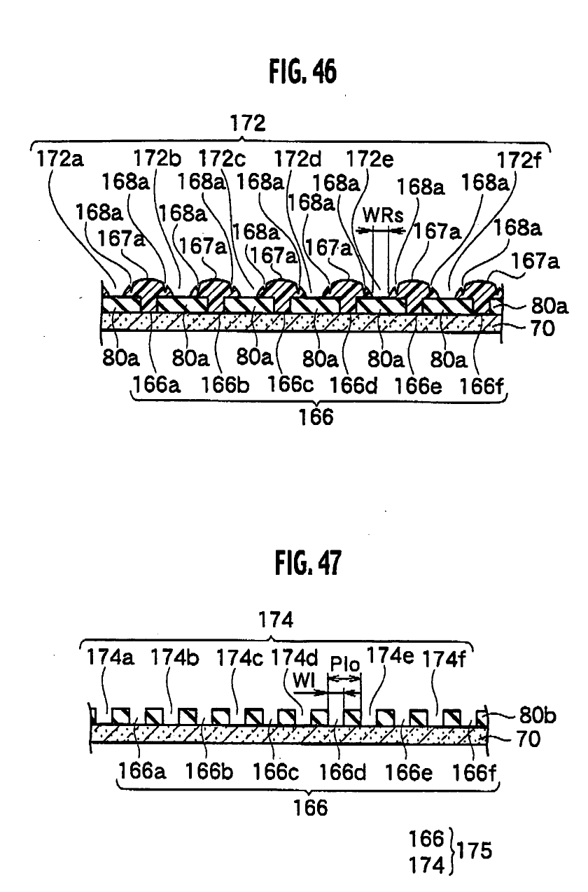

A thermal reflow process is performed by heating the semiconductor substrate 70 to a temperature above which the second resist pattern 170 is formed, for example at a temperature of 135° C. As a result, as shown in FIG. 46, a second reduced resist pattern 172 having reduced resist openings 172a to 172f which are provided by reducing the width WR of the resist openings 170a to 170f, is formed in the second reflow resist film 167a. The width WRs of the reduced resist openings 172a to 172f is reduced to about 70 nm almost equal to the resolution R. The pits 168a remain in the second reflow resist films 167a around the reduced resist openings 172a to 172f.

Using the second reflow resist films 167a as a mask, the underlying film 80a disposed in the reduced resist openings 172a to 172f is selectively removed by RIE or the like. Thereafter, the second reflow resist films 167a are removed by ashing or the like. As shown in FIG. 47, a second shrank pattern 174 having holes 174a to 174f between the respective holes 166a to 166f of the first shrank pattern 166 is formed in the underlying film 80b. As a result, a hole pattern 175 having a period PIo of about 140 nm and a width WI of about 70 nm is provided on the surface of the semiconductor substrate 70.

As described above, in a method for forming a pattern according to the second embodiment, it is possible to form the hole pattern 175 having the width WI almost equal to the value of the resolution R with the dense period PIo by partial exposure using the first and second photomasks 65c and 65d.

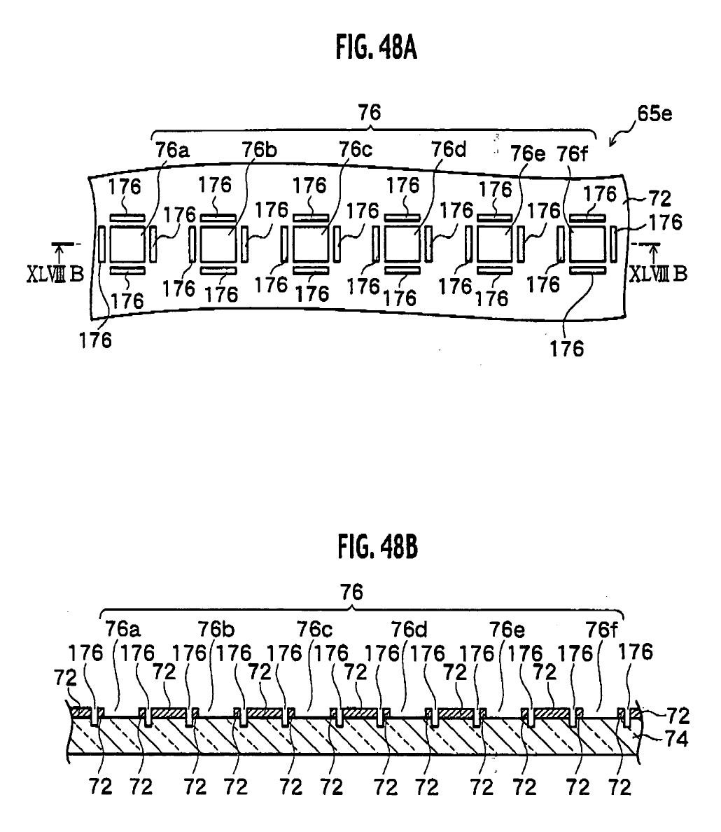

Furthermore, in the descriptions of the above described second embodiment, the SRAF transparent portion 156 in which the opaque film 72a and 72b on the transparent substrate 74 is removed is used. In order to further increase the resolution, a Revenson-type SRAF which shifts a phase of exposure light by about 180° by a phase shift technique may be used. For example, SRAF transparent portions 176 of the first photomask 65e shifts the phase of the exposure light by about 180° by providing trenches in the transparent substrate 74 as shown in FIGS. 48A and 48B. The Revenson-type SRAF transparent portions 176 are disposed also in the second photomask (omitted) as in the case of the first photomask 65e. The Revenson-type SRAF transparent portions 176 shown in FIGS. 48A and 48B have trenches provided in the transparent substrate 74. However, Revenson-type SRAF transparent portions are not limited to trenches. For example, phase shifters deposited in the SRAF transparent portions, which shift the phase of the exposure light by about 180°, may be acceptable.

### Other Embodiments

In the first and second embodiments of the present invention, as shown in FIG. 2, descriptions have been made by use of the example of the layout pattern 71 which has the dense pattern having the plurality of holes arrayed inline in one-dimension with the dense period Po. As a dense pattern, a plurality of holes may be arrayed on a plane in two-dimension. When a photomask is formed by dividing a layout pattern of a dense pattern in which a plurality of holes are arrayed in two-dimension, a width of transparent portions corresponding to the holes may be widened greater than the resolution R, and a spacing between the transparent portions on the plane should be sufficiently larger than the resolution R.

Various modifications will become possible for those skilled in the art after storing the teachings of the present disclosure without departing from the scope thereof.

1. A method for forming a pattern having a plurality of holes arrayed with a space therebetween that is less than a resolution of an exposure tool, comprising:
coating a first resist film onto an underlying film;
forming a first resist pattern having a plurality of first resist openings in the first resist film, each of the first resist openings having a width equal to or greater than the resolution of the exposure tool and arrayed with a spacing between adjacent resist openings equal to or greater than the resolution of the exposure tool;
forming a first shrank pattern having a plurality of first holes in the underlying film by a first shrink process applied to the first resist pattern, each of the first holes having a dimension equal to or less than the resolution of the exposure tool;
coating a second resist film onto the underlying film after removing the first resist film;
forming a second resist pattern having a plurality of second resist openings in the second resist film, each of the second resist openings having a width equal to or greater than the resolution of the exposure tool, arrayed between the first holes; and
forming a second shrank pattern having a plurality of second holes in the underlying film by a second shrink process applied to the second resist pattern, each of the second holes having a dimension equal to or less than the resolution of the exposure tool.

2. The method of claim 1, wherein the first shrink process comprises selectively removing the underlying film from first reduced resist openings, the first reduced resist openings provided by reducing the width of the first resist openings.

3. The method of claim 2, wherein the width of the first resist openings is reduced by a reflow of the first resist film by heating the first resist film.

4. The method of claim 2, wherein the width of the first resist openings is reduced by covering the first resist film with a first cross-linking layer by heating the first resist film, the first resist film containing a photo-induced acid generator, the first cross-linking layer formed by heating a first framed resist film containing a cross-linking agent reacting with acid generated from the first resist film, the first framed resist film coated on the first resist film.

5. The method of claim 1, wherein the first shrink process comprises selectively removing the underlying film from the first resist openings under a processing condition providing a processing conversion difference.

6. The method of claims 1, wherein the second shrink process comprises selectively removing the underlying film from second reduced resist openings, the second reduced resist openings provided by reducing the width of the second resist openings.

7. The method of claim 6, wherein the width of the second resist openings is reduced by a reflow of the second resist film by heating the second resist film.

8. The method of claim 6, wherein the width of the second resist openings is reduced by covering the second resist film with a second cross-linking layer by heating the second resist film, the second resist film containing a photo-induced acid generator, the second cross-linking layer formed by heating a second framed resist film containing a cross-linking agent reacting with acid generated from the second resist film, the second framed resist film coated on the second resist film.

9. The method of claims 1, wherein the second shrink process comprises selectively removing the underlying film from the second resist openings under a processing condition providing a processing conversion difference.

10. The method of claims 1, wherein the first and second resist patterns are formed by projecting transparent patterns having an assist pattern on photomasks by the exposure tool, the assist pattern having a width less than the resolution of the exposure tool and provided around a periphery of each of the transparent portions.

11. The method of claim 10, wherein the assist pattern shifts a phase of exposure light by 180° in relation to exposure light traveling through the transparent portions.

12. A method for manufacturing a semiconductor device having a plurality of holes arrayed with a space therebetween that is less than a resolution of an exposure tool, comprising:
depositing an underlying film on a surface of a semiconductor substrate;
coating a first resist film on the underlying film;
forming a first resist pattern having a plurality of resist openings in the first resist film, each of the first resist openings having a width equal to or greater than the resolution of the exposure tool and arrayed with a spacing between adjacent resist openings equal to or greater than the resolution of the exposure tool;
forming a first shrank pattern having a plurality of first holes in the underlying film by a first shrink process applied to the first resist pattern, each of the first holes having a dimension equal to or less than the resolution of the exposure tool;
coating a second resist film onto the underlying film after removing the first resist film;
forming a second resist pattern having a plurality of second resist openings in the second resist film, each of the second resist openings having a width equal to or greater than the resolution of the exposure tool, arrayed between the first holes; and
forming a second shrank pattern having a plurality of second holes in the underlying film by a second shrink process applied to the second resist pattern, each of the second holes having a dimension equal to or less than the resolution of the exposure tool.

13. The method of claim 12, wherein the first shrink process comprises selectively removing the underlying film from first reduced resist openings, the first reduced resist openings provided by reducing the width of the first resist openings.

14. The method of claim 13, the width of the first resist openings is reduced by a reflow of the first resist film by heating the first resist film.

15. The method of claim 13, wherein the width of the first resist openings is reduced by covering the first resist film with a first cross-linking layer by heating the first resist film, the first resist film containing a photo-induced acid generator, the first cross-linking layer formed by heating a first framed resist film containing a cross-linking agent reacting with acid generated from the first resist film, the first framed resist film coated on the first resist film.

16. The method of claim 12, wherein the first shrink process comprises selectively removing the underlying film from the first resist openings under a processing condition providing a processing conversion difference.

17. The method of claim 12, wherein the second shrink process comprises selectively removing the underlying film from second reduced resist openings, the second reduced resist openings provided by reducing the width of the second resist openings.

18. The method of claim 17, wherein the width of the second resist openings is reduced by a reflow of the second resist film by heating the second resist film.

19. The method of claim 17, wherein the width of the second resist openings is reduced by covering the second resist film with a second cross-linking layer by heating the second resist film, the second resist film containing a photo-induced acid generator, the second cross-linking layer formed by heating a second framed resist film containing a cross-linking agent reacting with acid generated from the second resist film, the second framed resist film coated on the second resist film.

20. The method of claim 12, wherein the second shrink process comprises selectively removing the underlying film from the second resist openings under a processing condition providing a processing conversion difference.

21. The method of claim 12, wherein the first and second resist patterns are formed by projecting transparent patterns having an assist pattern on photomasks by the exposure tool, the assist pattern having a width less than the resolution of the exposure tool and provided around a periphery of each of the transparent portions.

22. The method of claim 21, wherein the assist pattern shifts a phase of exposure light by 180° in relation to exposure light traveling through the transparent portions.
